(19) United States
(12) Patent Application Publication
(10) Pub. No.: US 2018/0130942 A1
(43) Pub. Date: May 10, 2018

(54) PIEZOELECTRIC FILM AND METHOD FOR MANUFACTURING SAME

(71) Applicant: FUJIFILM Corporation, Tokyo (JP)

(72) Inventor: Takami ARAKAWA, Kanagawa (JP)

(73) Assignee: FUJIFILM Corporation, Tokyo (JP)

(21) Appl. No.: 15/861,489

(22) Filed: Jan. 3, 2018

Related U.S. Application Data
(62) Division of application No. 14/870,500, filed on Sep. 30, 2015.
Application No. 14/870,500 is a continuation of application No. PCT/JP2014/059124, filed on Mar. 28, 2014.

(30) Foreign Application Priority Data
Apr. 1, 2013 (JP) 2013-076022

(51) Int. Cl. H01L 41/187; C23C 14/56; C23C 14/08; C04B 35/622; C04B 35/493; H01L 41/316; B41J 2/14; H01L 41/09; C04B 35/499; C23C 14/34

(52) U.S. Cl. CPC H01L 41/1876; C23C 14/564; C23C 14/3414; C23C 14/088; C04B 2235/80; C04B 2235/76; C04B 2235/721; C04B 2235/422; C04B 2235/3255; C04B 2235/3251; C04B 2235/3244; C04B 2235/3232; C04B 35/62218; C04B 35/493; H01L 41/316; B41J 2202/03; B41J 2/14233; H01L 41/0973; C04B 35/499; C23C 14/34; C23C 14/08

(57) ABSTRACT

Provided is a piezoelectric film having a perovskite type crystal structure represented by the following Formula (P), in which a piezoelectric constant d₃₁ (pm/V), a relative dielectric constant ∈ (−), and a dielectric loss tan δ (−) satisfy (d₃₁)²/(∈×tan δ×1000)>3. In addition, a method for manufacturing the above piezoelectric film is provided.

Pbₓ[(ZrₐTi₁₋ₐ)_{1-y}Nb_{y}]O_{z} (P)

(in Formula (P), x represents a lead content, y represents a Nb content (B site doping amount), z represents an oxygen content, a represents a Zr/Ti ratio, and y>0.14, and although x=1.0 and z=3 is standard, numerical values of x and z may deviate from 1.0 and 3, respectively, within a range where a perovskite structure can be adopted.)

### CROSS-REFERENCE TO RELATED APPLICATIONS

The present application is a Divisional of U.S. application Ser. No. 14/870,500 filed Sep. 30, 2015, which is a Continuation of PCT International Application No. PCT/JP2014/059124 filed Mar. 28, 2014 claiming priority under 35 U.S.C § 119(a) to Japanese Patent Application No. 2013-076022 filed Apr. 1, 2013. Each of the above applications is hereby expressly incorporated by reference, in their entirety, into the present application.

### BACKGROUND OF THE INVENTION

### 1. Field of the Invention

The present invention relates to a piezoelectric film and a method for manufacturing a piezoelectric film and, particularly, relates to a piezoelectric film and a method for manufacturing a piezoelectric film, in which the supply current and the power consumption are reduced.

### 2. Description of the Related Art

A piezoelectric element is used as a piezoelectric actuator or the like which is mounted in an ink jet recording head, the piezoelectric element including: a piezoelectric material which expands and contracts in response to an increase and decrease in electric field application intensity; and an electrode which applies an electric field to the piezoelectric material. As the piezoelectric material, a perovskite type oxide such as lead zirconate titanate (PZT) is widely used. The piezoelectric material is a ferroelectric capable of spontaneous polarization when an electric field is not applied thereto.

It has been known since the 1960s that, in PZT to which various donor ions having a higher valence than substituted ions are added, characteristics such as ferroelectric performance are improved to be higher than those of pure PZT. As a donor ion which substitutes Pb′ in the A site, various lanthanoid cations such as Bi³⁺ and La³⁺ are known. As a donor ion which substitutes Zr⁴⁺ and/or Ti⁴⁺ in the B site, for example, V⁵⁺, Nb⁵⁺, Ta⁵⁺, Sb⁵⁺, Mo⁶⁺, and W⁶⁺ are known.

For example, JP2005-100660A and JP2008-266770A describe PZT which is highly doped with Nb. JP2005-100660A describes that, by PZT being highly doped with Nb, oxygen deficiency can be reduced, the leakage current can be reduced, and ferroelectric hysteresis characteristics are improved. In addition, JP2008-266770A describes that piezoelectric characteristics are improved.

JP2011-066343A describes that, by adjusting a carbon intensity ratio, which is defined as a ratio of a maximum carbon intensity to a minimum carbon intensity in a piezoelectric film, to be in a range of 8 to 28, the relative dielectric constant can be increased, and the piezoelectric constant can be improved.

### SUMMARY OF THE INVENTION

In a method for manufacturing a piezoelectric film of the related art, the piezoelectric constant is improved; however, since the relative dielectric constant (∈) and the dielectric loss (tan δ) are extremely high, there is a problem in that the power consumption increases. JP2005-100660A and JP2008-266770A describe a technique of improving a piezoelectric constant but does not provide a description of how the relative dielectric constant (∈) and the dielectric loss (tan δ) are changed, that is, how the supply current to a piezoelectric film and the power consumption are changed and how to control the supply current and the power consumption.

According to the theory of a piezoelectric material in the related art, a piezoelectric constant d₃₁ is expressed by the following Formula (A) where k₃₁ represents an electromechanical coupling factor and Y represents a Young's modulus (hardness) of a piezoelectric film.

$${d}_{31} = {k}_{31} \sqrt{\frac{ɛ}{Y}} \qquad ( A )$$

In the theory, as expressed by Formula (A), when the Young's modulus Y of a piezoelectric film is substantially the same as the electromechanical coupling factor k₃₁, the piezoelectric constant d₃₁ increases along with an increase in the relative dielectric constant ∈. Therefore, an increase in the relative dielectric constant ∈ caused by an increase in the piezoelectric constant d₃₁ is understood as a matter of course, and a technique of decreasing the relative dielectric constant ∈ and the dielectric loss tan δ while fixing the piezoelectric constant d₃₁ is not considered. In JP2011-066343A, a technique of increasing the relative dielectric constant is considered, but a relationship between the dielectric constant and piezoelectric characteristics is not considered in detail.

The present invention has been made in consideration of the above-described circumstances, and an object thereof is to provide a piezoelectric film and a method for manufacturing a piezoelectric film, in which the relative dielectric constant ∈ and the dielectric loss tan S are suppressed while maintaining the piezoelectric constant, which is improved by donor ions being doped, that is, the supply current to a piezoelectric film and the power consumption are reduced.

In order to achieve the above-described object, according to the present invention, there is provided a piezoelectric film having a perovskite type crystal structure represented by the following Formula (P), in which a piezoelectric constant d₃₁ (pm/V), a relative dielectric constant ∈ (−), and a dielectric loss tan δ (−) satisfy (d₃₁)²/(∈×tan δ×1000)>3.

Pbₓ[(ZrₐTi₁₋ₐ)_{1-y}Nb_{y}]O_{z} (P)

(where x represents a lead content, y represents a Nb content (B site doping amount), z represents an oxygen content, a represents a Zr/Ti ratio, and y>0.14, and although x=1.0 and z=3 is standard, numerical values of x and z may deviate from 1.0 and 3, respectively, within a range where a perovskite structure can be adopted.)

The piezoelectric constant d₃₁ shows a displacement relative to an applied voltage. Therefore, as the piezoelectric constant d₃₁ increases, the displacement relative to the voltage increases. The relative dielectric constant ∈ is a physical amount representing the degree of response of atoms or the like in a material when an electric field is applied to the material. As the relative dielectric constant ∈ increases, a high supply current is required. The dielectric loss tan δ represents a constant representing the degree of loss of electric energy loss when an AC electric field is applied to a piezoelectric material. As the dielectric loss tan δ increases, the power consumption increases. Accordingly, an increase in the numerical values in the above-described Formula implies that the efficiency of a piezoelectric film is improved.

According to the present invention, a value obtained by (d₃₁)²/(∈×tan δ×1000) exceeds 3. In the related art, in a piezoelectric film having a high piezoelectric constant d₃₁, the relative dielectric constant ∈ is also high. However, by suppressing the relative dielectric constant ∈ and the dielectric loss tan δ to be low and adjusting the value of the Formula to exceed 3, the supply current to a piezoelectric film and the power consumption can be reduced, and the piezoelectric constant d₃₁ and the efficiency of the piezoelectric film can be improved.

In the piezoelectric film according to an aspect of the present invention, it is preferable that crystals constituting the perovskite type crystal structure contain crystals, which are oriented in a (100) direction or a (001) direction, as a major component.

In the piezoelectric film according to the above-described aspect of the present invention, the crystal structure constituting the piezoelectric film contains crystals, which are oriented in a (100) direction or a (001) direction, as a major component; as a result, the piezoelectric constant d₃₁ can be improved, the numerical value (d₃₁)²/(∈×tan δ×1000) can be increased, and the piezoelectric film can be driven at a low voltage.

In the piezoelectric film according to another aspect of the present invention, it is preferable that the piezoelectric film has a thickness of 2 μm to 10 μm.

When the thickness of the piezoelectric film is within the above-described range, the relative dielectric constant ∈ and the dielectric loss tan δ of the piezoelectric film are increased. In the piezoelectric film according to the above-described aspect of the present invention, even when the thickness of the piezoelectric film is within the above-described range, the efficiency of the piezoelectric film can be improved.

In the piezoelectric film according to still another aspect of the present invention, it is preferable that y in Formula (P) satisfies y≥0.18.

When the doping amount (y) of Nb in the piezoelectric film is 18% or more, the piezoelectric constant d₃₁ is improved; however, the relative dielectric constant ∈ and the dielectric loss tan δ of the piezoelectric film are increased. In the piezoelectric film according to the above-described aspect of the present invention, even when the doping amount (y) of Nb is 18% or more, the efficiency of the piezoelectric film can be improved.

In the piezoelectric film according to still another aspect of the present invention, it is preferable that the crystals constituting the perovskite type crystal structure are columnar crystals.

In the piezoelectric film according to the above-described aspect of the present invention, the crystal structure constituting the piezoelectric film contains columnar crystals; as a result, the crystal orientation of the piezoelectric film can be aligned, and high piezoelectric performance can be obtained.

In order to achieve the above-described object, according to the present invention, there is provided a piezoelectric film having a perovskite type crystal structure represented by the following Formula (P), in which the piezoelectric film has a thickness of 2 μm or more, and the number of particles containing carbon and having a particle size of 200 nm or more, which are deposited on a surface of the piezoelectric film, is 1000 particle/μm² or less.

Pbₓ[(ZrₐTi₁₋ₐ)_{1-y}Nb_{y}]O_{z} (P)

(where x represents a lead content, y represents a Nb content (B site doping amount), z represents an oxygen content, a represents a Zr/Ti ratio, and y>0.14, and although x=1.0 and z=3 is standard, numerical values of x and z may deviate from 1.0 and 3, respectively, within a range where a perovskite structure can be adopted.)

As the doping amount of Nb increases, carbon is more likely to be incorporated into the piezoelectric film, and the power consumption increases. According to the present invention, in the piezoelectric film in which the doping amount (y) of Nb is 14% or more and the thickness of the piezoelectric film is 2 μm or more and into which carbon is likely to be incorporated, the number of deposited particles containing carbon and having a particle size of 200 nm or more, which is an index indicating the carbon content in the piezoelectric film, is 1000 particle/μm² or less. With the above-described configuration, the carbon content in the piezoelectric film can be reduced, the piezoelectric constant d₃₁ of the piezoelectric film can be increased, and the power consumption of the piezoelectric film can be reduced.

In the piezoelectric film according to still another aspect of the present invention, it is preferable that the piezoelectric film has a thickness of 3 μm or more.

The piezoelectric film according to the above-described aspect of the present invention is efficient as a piezoelectric film having a thickness of 3 μm or more into which carbon is likely to be incorporated.

In order to achieve the above-described object, according to the present invention, there is provided a method for manufacturing a piezoelectric film, the piezoelectric film having a perovskite type crystal structure represented by the following Formula (P), the method including forming a piezoelectric film with a sputtering method using a raw material target having a composition corresponding to a film composition for forming the piezoelectric film and having a carbon concentration of 200 ppm or lower.

Pbₓ[(ZrₐTi₁₋ₐ)_{1-y}Nb_{y}]O_{z} (P)

(where x represents a lead content, y represents a Nb content (B site doping amount), z represents an oxygen content, a represents a Zr/Ti ratio, and y>0.14, and although x=1.0 and z=3 is standard, numerical values of x and z may deviate from 1.0 and 3, respectively, within a range where a perovskite structure can be adopted.)

According to the present invention, a piezoelectric film is formed with a sputtering method using a raw material target having a low carbon concentration of 200 ppm; as a result, the carbon content in the formed piezoelectric film can be reduced. Accordingly, by reducing the carbon content in the piezoelectric film, the relative dielectric constant ∈ and the dielectric loss tan δ can be suppressed, and a piezoelectric film with reduced supply current and power consumption can be formed.

In the piezoelectric film and the method for manufacturing a piezoelectric film according to the present invention, the piezoelectric constant can be improved by doping the piezoelectric film with more than 14% of Nb. Further, by reducing the carbon content, the relative dielectric constant ∈ and tan δ can be reduced while maintaining the piezoelectric constant. Therefore, a piezoelectric film having reduced supply current and power consumption and high efficiency can be obtained.

### BRIEF DESCRIPTION OF THE DRAWINGS

FIG. 1A is a secondary electron image of a formed piezoelectric film.

FIG. 1B is a backscattered electron image of the formed piezoelectric film.

FIG. 2 is a schematic cross-sectional view showing a sputtering apparatus.

FIG. 3 is a diagram showing a method for measuring a plasma potential Vs and a floating potential Vf.

FIG. 4 is a cross-sectional view showing a piezoelectric element and a structure of an ink jet recording apparatus.

FIG. 5 is a diagram schematically showing an overall configuration of the ink jet recording apparatus.

FIG. 6 is a diagram showing an XRD (X-ray diffraction) pattern of Example 1.

FIG. 7 is a table showing the results of Test Example 1.

FIG. 8 is a table showing the results of Test Example 2.

FIG. 9 is a table showing the results of Test Example 2.

### DESCRIPTION OF THE PREFERRED EMBODIMENTS

Hereinafter, preferable embodiments of a piezoelectric film and a method for manufacturing a piezoelectric film according to the present invention will be described with reference to the accompanying drawings.

[Piezoelectric Film]

The piezoelectric film according to the present invention has a perovskite type crystal structure represented by the following Formula (P) as a major component.

Pbₓ[(ZrₐTi₁₋ₐ)_{1-y}Nb_{y}]O_{z} (P)

In Formula (P), x represents a lead content, y represents a Nb content (B site doping amount), z represents an oxygen content, a represents a Zr/Ti ratio, and y>0.14, and although x=1.0 and z=3 is standard, numerical values of x and z may deviate from 1.0 and 3, respectively, within a range where a perovskite structure can be adopted.

It is known that a PZT perovskite type oxide exhibits high piezoelectric performance at and near a morphotropic phase boundary (MPB). The PZT system becomes a rhombohedral system when Zr is rich, becomes a tetragonal system when Ti is rich, and becomes a boundary between a rhombohedral system and a tetragonal system, that is, MPB when a Zr/Ti molar ratio is about 55/45. Accordingly, it is preferable that a in Formula (P) represents a MPB composition or an equivalent thereof. Specifically, it is preferable that 0.45<a<0.55.

The Nb content satisfies y>0.14 and preferably y≥0.18. By increasing the Nb content, piezoelectric characteristics can be improved. In addition, when the Nb content is excessively high, a perovskite structure cannot be formed, and a non-piezoelectric heterogeneous phase called a pyrochlore phase is formed, which is not preferable. It is preferable that the upper limit of the Nb content satisfies y≤0.23.

[Characteristics of Piezoelectric Film]

The power consumption in the piezoelectric film is in proportion to ∈×tan δ×V² when the applied voltage (V) is represented by V, the relative dielectric constant (−) is represented by ∈, and the dielectric loss (−) is represented by tan δ. In order to obtain the same piezoelectric potential, the applied voltage should be in inverse proportion to the piezoelectric constant d₃₁ (pm/V). Therefore, (∈×tan δ)/(d₃₁)² is an index for the power consumption. That is, an increase in the numerical value of the following Expression (B) implies that the efficiency of the piezoelectric film is improved. In the denominator, ∈×tan δ is multiplied by 1000 to simplify the numerical value.

(d₃₁)²/(∈×tan δ×1000) (B)

In the embodiment, the value in Expression (B) exceeds 3.

In a piezoelectric film doped with more than 14% of Nb, the piezoelectric constant d₃₁ is improved but the relative dielectric constant ∈ and the dielectric loss tan δ are also increased; therefore, the value of Expression (B) does not exceed 3, and the efficiency is poor. Therefore, even when the piezoelectric constant is high and the power supply voltage is reduced, heat generation cannot be suppressed.

When the number of particles containing carbon and having a particle size of 200 nm or more, which are deposited on a surface of the piezoelectric film, is 1000 particle/μm² or less, a piezoelectric film doped with 14% or more of Nb in which the value of Expression (B) exceeds 3 can be obtained.

Here, the deposited particles containing carbon and having a particle size of 200 nm or more will be described.

When a piezoelectric film is formed using a sputtering method, in general, a carbonate, an acetate, or the like is used as a raw material of a sintering target, and a carbon container is used as a sintering container. Therefore, even when carbon is not actively introduced, a certain amount of carbon is present in the piezoelectric film. In addition, in a piezoelectric film which is formed using a Metal Organic Chemical Vapor Deposition (MO-CVD) method or a sol-gel method, a carbon-containing material such as a complex or an alkoxide is used, and it is unavoidable for the piezoelectric film to contain carbon.

In the present invention, the piezoelectric film is doped with more than 14% or more of Nb, and the doping amount of Nb is increased. In particular, when the doping amount of Nb exceeds 14%, the number of deposited particles containing carbon and having a particle size of 200 nm or more is significantly increased.

The reason why the amount of deposited particles containing carbon when the doping amount of Nb exceeds 14% is not clear but is presumed to be as follows. Nb is embedded into a site of ZrO₂ or TiO₂ as Nb₂O₅. When the doping amount of Nb is 14% or less, the Nb content is low. Therefore, oxygen is released, and the released oxygen is bonded with carbon to produce CO₂. Therefore, carbon remaining in the piezoelectric film can be prevented. However, when the Nb content is increased such that the doping amount of Nb exceeds 14%, the supply of oxygen is excessive, oxygen is likely to be incorporated into the film, and it is difficult to release oxygen from the film.

The doping of more than 14% of Nb is effective to improve the piezoelectric constant. Therefore, even a film in which the number of deposited particles containing carbon is large can be driven as a piezoelectric film. However, since the relative dielectric constant ∈ and the dielectric loss tan δ are high, there are problems in that the power consumption increases, the size of a drive power supply increases, and the amount of heat generated in a piezoelectric element increases.

The carbon content in the piezoelectric film can be controlled by controlling the carbon content in a target used during the film formation. In the case of a film in which the doping amount of Nb is 14% or less, even when the carbon content in the film formation target is high, the carbon content in the piezoelectric film is low, and it is not necessary to control the carbon content.

In the above-described configuration, by increasing the doping amount of Nb in the piezoelectric film, the piezoelectric constant can be improved; however, the relative dielectric constant ∈ and the dielectric loss tan δ also increase. Therefore, the supply current and the power consumption increase. In addition, carbon which has been contained in the raw material target of the piezoelectric film is likely to remain in the piezoelectric film. However, using a film formation method described below, the carbon concentration in the raw material target can be reduced, and the number of particles containing carbon and having a particle size of 200 nm or more, which are deposited on the surface of the piezoelectric film, can be made to be 1000 particle/μm² or less. As a result, while maintaining the piezoelectric constant after Nb doping, the relative dielectric constant ∈ and the dielectric loss tan δ can be reduced. Therefore, the supply current and the power consumption can be reduced.

The deposited particles containing carbon and having a particle size of 200 nm or more are black particles having a particle size of 200 nm or more which can be observed using a normal optical microscope. For example, an image is taken in a visual field of about 300 μm×500 μm using an optical microscope, and the number of visually recognized particles is measured. These particles contain Nb in an amount exceeding 14% unlike “particles” of a deposit which are peeled off from a wall or the like of a vacuum film formation apparatus of the related art during film formation. The formation of these particles is a characteristic of a PZT thin film having a high piezoelectric constant, and these particles may also be formed, for example, when a film formation chamber is cleaned.

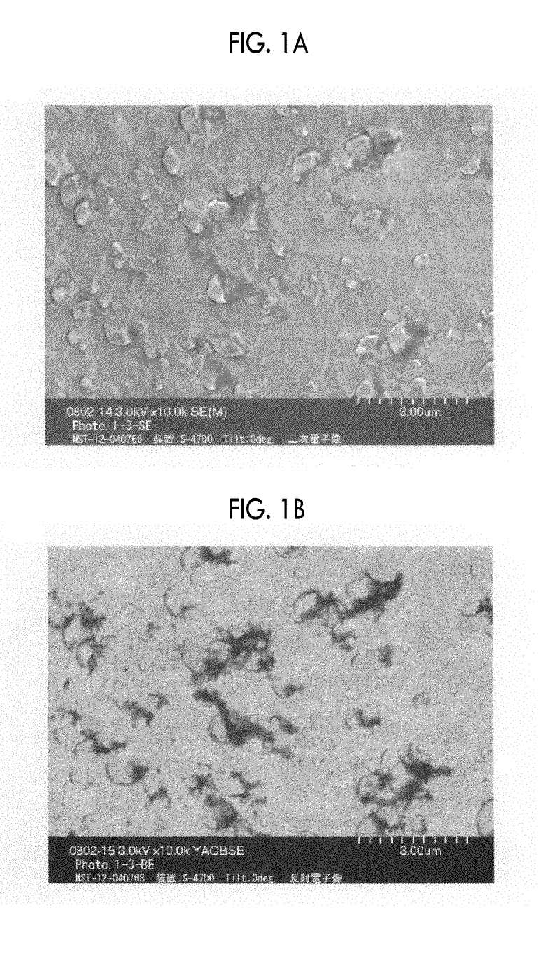

When a portion of black particles is observed as a secondary electron image using an optical microscope, particulate deposits shown in FIG. 1A are observed. When these particles are observed as a backscattered electron image, as shown in FIG. 1B, the black contrast is observed at regions near the deposits, which implies the deposition of light elements. These black portions are analyzed by Energy Dispersive X-ray spectrometry (EDX), and the deposition of carbon can be verified. In the case of “particles” of the related art, when deposited particles are compared to portions where particles are not deposited, there is no difference between the analysis results because the same degree of carbon contamination is present. Therefore, it can be verified that deposited particles contain carbon.

It is preferable that the crystal structure constituting the piezoelectric film contains crystals, which are oriented in a (100) direction or a (001) direction, as a major component. By using the piezoelectric film having a crystal structure containing crystals, which are oriented in a (100) direction or a (001) direction, as a major component, a high piezoelectric constant can be obtained. “Containing crystals, which are oriented in a (100) direction or a (001) direction, as a major component” represents that the orientation degree of the crystals in the (100) direction or the (001) direction is 60% or higher. The orientation degree is more preferably 80% or higher. In addition, the orientation degree is obtained using the expression “Orientation=Σ(Peak in (100) Direction)/Σ(Peak in (100) Direction)+Peak in (110) Direction+Peak in (111) Direction)”. The peak in the (100) direction may be replaced with a peak in a (001) direction.

In addition, the thickness of the piezoelectric film is preferably 2 μm or more. By controlling the thickness to be 2 μm or more, the deposition of particles containing carbon, which occurs when the doping amount of Nb exceeds 14%, is significant. The reason for this is not clear but is presumed to be as follows.

Carbon incorporated into the piezoelectric film is released as CO₂ from the piezoelectric film by the above-described mechanism. Even in the piezoelectric film in which the doping amount of Nb exceeds 14%, carbon is also released although the amount thereof is smaller than that of a piezoelectric film in which the doping amount of Nb is 14% or less. Therefore, in a piezoelectric film having a thickness of less than 2 μm, the amount of carbon remaining is small. When the thickness of the piezoelectric film is 2 μm or more, in a method of the related art, the amount of carbon remaining increases. Therefore, the present invention can be efficiently practiced. The thickness of the piezoelectric film is more preferably 3 μm or more.

An increase in the thickness of the piezoelectric film is efficient from the viewpoint of, for example, reducing the drive voltage of a piezoelectric thin film device. Not only a piezoelectric film having a thickness of less than 2 μm but also a piezoelectric film having a thickness of 2 μm or more are required. In addition, a piezoelectric film having a thickness of 10 μm or less is preferable because it can exhibit a displacement without being restricted. In addition, in a method of the related art in which bulk ceramics are polished and bonded, it is difficult to form a piezoelectric film having a thickness of 20 μm or less, and the particle size is in the order of micrometers. Therefore, convex and concave portions are formed on the surface of the piezoelectric film.

In the piezoelectric film, as shown below, it is preferable that columnar crystals are formed using a vapor phase epitaxial method. By forming the film using a vapor phase epitaxial method, the surface of the piezoelectric film can be made to be smooth. In addition, a piezoelectric film having a thin thickness can be formed.

[Method for Manufacturing Piezoelectric Film]

The piezoelectric film which has the perovskite type crystal structure represented by Formula (P) as a major component can be formed using a non-thermal equilibrium process. Preferable examples of a method for manufacturing the piezoelectric film according to the present invention include a sputtering method, a plasma chemical vapor deposition (CVD) method, a firing and quenching method, an annealing and quenching method, and a thermal spraying and quenching method. Among these, a sputtering method is particularly preferable.

In a thermal equilibrium process such as a sol-gel method, it is difficult to dope a film with a high concentration of an additive having a different valence, and it is necessary to take a countermeasure such as use of a sintering additive or an acceptor ion. In the non-thermal equilibrium process, a film can be doped with a high concentration of donor ions without taking the above-described countermeasure.

In addition, in the non-thermal equilibrium process, a film can be formed at a relatively low film formation temperature or lower at which Si and Pb react with each other. Therefore, a film can be formed on a Si substrate having superior workability, which is not preferable.

As factors which determine characteristics of a film to be formed using a sputtering method, the film formation temperature, the kind of a substrate, the composition of a underlayer which may be formed on the substrate in advance, the surface energy of the substrate, the film formation pressure, the oxygen content in atmospheric gas, supplied power, the distance between the substrate and the target, the temperature and density of electrons in plasma, the density of active species in plasma, and the service life of active species can be considered.

For example, a high-quality film can be formed by optimizing any one of the film formation temperature Ts, Vs−Vf (Vs represents the plasma potential in plasma during film formation, and Vf represents the floating potential during film formation), Vs, and the distance between the substrate and the target. That is, when characteristics of a film are plotted in a graph in which the horizontal axis represents the film formation temperature Ts and the vertical axis represents any one of Vs−Vf, Vs, and the distance D between the substrate and the target, a high-quality film can be formed in a certain range.

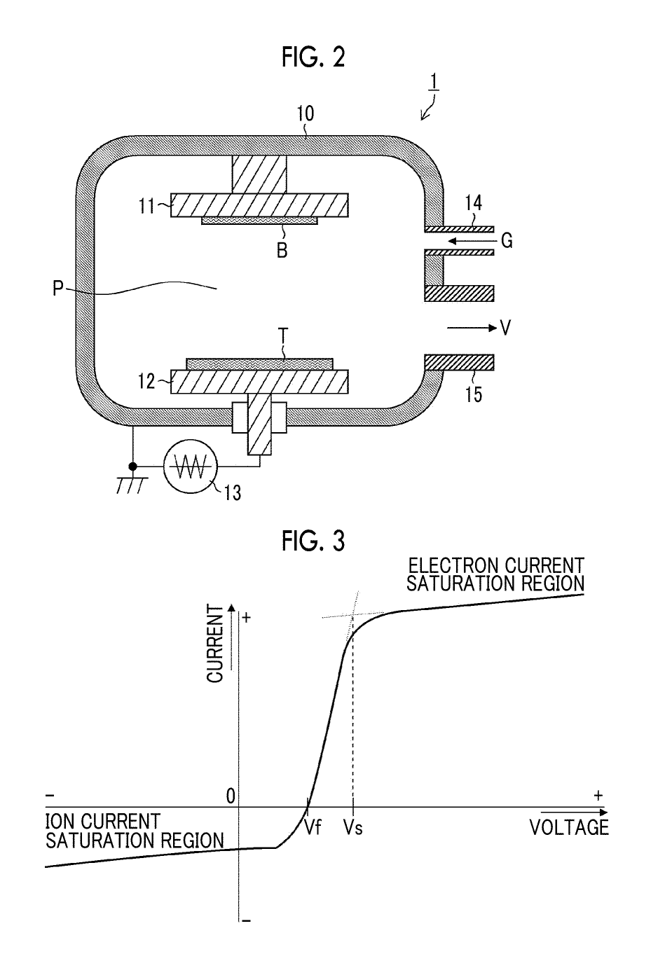

A configuration example of a sputtering apparatus and the film formation state will be described with reference to FIG. 2. Here, a radio frequency (RF) sputtering apparatus using a RF power supply will be described as an example. However, a direct current (DC) sputtering apparatus using a DC power supply can also be used. FIG. 2 is a schematic cross-sectional view showing the entire apparatus.

As shown in FIG. 2, a sputtering apparatus 1 is configured to include a vacuum chamber 10 including: a substrate holder 11 such as an electrostatic chuck that can hold a film formation substrate B and can heat the film formation substrate B to a predetermined temperature; and a plasma electrode (cathode electrode) 12 that generates plasma.

The substrate holder 11 and the plasma electrode 12 are arranged apart from each other to face each other, and a target T is mounted on the plasma electrode 12. The plasma electrode 12 is connected to an RF power supply 13.

A gas introduction pipe 14 and a gas discharge pipe 15 are attached to the vacuum chamber 10, in which the gas introduction pipe 14 introduces gas G, which is required for film formation, into the vacuum chamber 10, and the gas discharge pipe 15 discharges gas V from the vacuum chamber 10. As the gas G, for example, Ar or Ar/O₂ mixed gas is used.

When the piezoelectric film according to the present invention is formed using a sputtering method, it is preferable that the film formation conditions including the film formation temperature Ts (° C.) and Vs−Vf (V), which is a difference between the plasma potential Vs (V) and the floating potential Vf (V) in plasma during film formation, satisfy the following Expressions (1) and (2), and it is more preferable that the film formation conditions satisfy the following Expressions (1) to (3).

Ts(° C.)≥400 (1)

−0.2Ts+100<Vs−Vf(V)<−0.2Ts+130 (2)

10≤Vs−Vf(V)≤35 (3)

The potential of a plasma space P is the plasma potential Vs (V). Typically, the film formation substrate B is an insulator and is electrically insulated from the ground. Accordingly, the film formation substrate B is in a floating state, and the potential thereof is the floating potential Vf (V). It is considered that constituent elements of the target positioned between the target T and the film formation substrate B collide with the film formation substrate B during film formation with a kinetic energy corresponding to the acceleration voltage of the potential difference Vs−Vf between the potential of the plasma space P and the potential of the film formation substrate B.

The plasma potential Vs and the floating potential Vf can be measured using a Langmuir probe. A tip end of the Langmuir probe is inserted into the plasma space P, and the voltage applied to the probe is changed. As a result, for example, current-voltage characteristics shown in FIG. 3 are obtained (“The Essentials of Plasmas and Film Formation”, p. 90, Mitsuharu Konuma, published by Nikkan Kogyo Shimbunsha, Japan). In FIG. 3, a probe potential at which the current is 0 is the floating potential Vf. In this state, the amounts of the ion current and the electron current to the probe surface are significant. The metal surface or the substrate surface which is insulated has this potential. When the probe potential is higher than the floating potential Vf, the ion current gradually decreases, and only the electron current reaches the probe. The voltage at this boundary is the plasma potential Vs. Vs−Vf can be changed by providing the ground between the substrate and the target.

It is known that, when a PZT piezoelectric film is formed by sputtering at a high temperature, the loss of Pb is likely to occur. The loss of Pb is dependent on not only the film formation temperature but also Vs−Vf. Among Pb, Zr, and Ti which are the constituent elements of PZT, Pb has the highest sputtering rate and is likely to be sputtered. For example, Table 8.1.7 of “Vacuum Handbook” (edited by Ulvac Inc., published by Ohmsha, Japan) shows the following sputtering rates under conditions of Ar ions at 300 eV: Pb=0.75, Zr=0.48, Ti=0.65. “Being likely to be sputtered” represents that sputtered atoms are likely to be re-sputtered after being deposited on the substrate surface. It is considered that, as a difference between the plasma potential and the potential of the substrate increases, that is, as a difference Vs−Vf increases, the re-sputtering rate increases, and the loss of Pb is likely to occur.

Under a condition where any one of the film formation temperature Ts and Vs−Vf is extremely low, perovskite crystals cannot be grown favorably. In addition, under a condition where any one of the film formation temperature Ts and Vs−Vf is extremely high, the loss of Pb is likely to occur. That is, under a condition which satisfies Expression (1) Ts (° C.)≥400, when the film formation temperature Ts is relatively low, it is necessary to set Vs−Vf to be relatively high in order to favorably grow perovskite crystals. In addition, when the film formation temperature Ts is relatively high, it is necessary to set Vs−Vf to be relatively low in order to suppress the loss of Pb. This is expressed by Expression (2).

In addition, by determining film formation conditions in a range satisfying Expressions (1) to (3) during the formation of a PZT piezoelectric film, a piezoelectric film having a high piezoelectric constant can be obtained.

In the present invention, the number of particles containing carbon and having a particle size of 200 nm or more, which are deposited on the surface of the piezoelectric film, is 1000 particle/μm². In order to satisfy this condition, for example, by using a target having a carbon concentration of 200 ppm or lower in the raw material target, a piezoelectric film can be formed using a sputtering method. The carbon concentration can be measured using a high-frequency combustion-infrared absorption method. For example, a high-frequency combustion-infrared absorption apparatus CS-444 (manufactured by LECO Japan Corporation) is used. The carbon concentration in a raw material target which is usually used for manufacturing a piezoelectric film of the related art is about 600 ppm when measured.

The raw material target in which the carbon concentration is reduced can be formed as follows. In general, the raw material target can be formed using a sputtering method by preliminarily firing the crushed raw material powder at a low temperature, re-crushing the fired powder, applying a pressure to the re-crushed powder to consolidate the powder, and firing the consolidated powder at a temperature higher than the preliminary firing temperature. In a usual sintering method, a sintered compact in which a large amount of carbon remains (for example, 600 ppm) is obtained. In order to reduce the carbon concentration in the raw material (target), carbon can be removed during preliminary firing and firing by increasing the preliminary firing temperature, the preliminary firing time, the firing temperature, and the firing time of the powder. Therefore, the carbon concentration in the target can be reduced. In addition to general sintering, a bulk body is degreased by heating it for a long period of time at a temperature lower than a main firing temperature of pellet sintering, and the firing temperature is increased. As a result, a target having a low carbon concentration can be manufactured.

In addition, in the stage of raw material powder, the carbon concentration can be reduced by irradiating oxygen plasma and using UV rays of a low-pressure mercury lamp and an excimer light in advance. In addition, an UV ozone method is also efficient in which powder undergoes UV irradiation and ozone exposure by irradiating oxygen with UV rays to produce ozone. By using the raw material powder which is treated in advance as described above, the carbon concentration in the manufactured raw material target can be reduced.

[Piezoelectric Element and Ink Jet Recording Head]

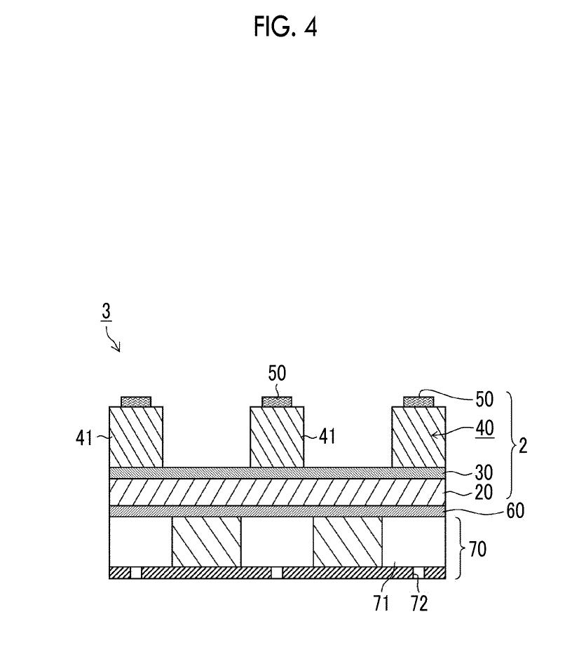

The structure of a piezoelectric element according to an embodiment of the present invention and an ink jet recording head (liquid ejecting apparatus) including the same will be described with reference to FIG. 4. FIG. 4 is a cross-sectional view showing major parts of the ink jet recording head. For easy visual recognition, the reduced scale of components is different from the actual scale.

A piezoelectric element 2 is an element in which a lower electrode 30, a piezoelectric film 40, and an upper electrode 50 are sequentially laminated on a substrate 20, and an electric field is applied from the lower electrode 30 and the upper electrode 50 to the piezoelectric film 40 in a thickness direction. The piezoelectric film 40 is the piezoelectric film according to the present invention containing a perovskite type oxide represented by Formula (P).

The lower electrode 30 is formed on the entire surface of the substrate 20. The piezoelectric film 40 having a pattern in which linear convex portions 41 extending from the front side to the depth side in the drawing are arranged in a stripe shape is formed on the lower electrode 30. The upper electrode 50 is formed on each of the convex portions 41.

The pattern of the piezoelectric film 40 is not limited to that shown in the drawing and can be appropriately designed. In addition, the piezoelectric film 40 may be a continuous film. However, by forming the piezoelectric film 40 using the pattern in which the plural convex portions 41 are separated from each other instead of using a continuous film, each of the convex portions 41 smoothly expands and contracts, and a larger displacement can be obtained, which is preferable.

The substrate 20 is not particularly limited, and examples thereof include substrates formed of silicon, glass, stainless steel (Steel use Stainless (SUS)), yttrium-stabilized zirconia (YSZ), alumina, sapphire, silicon carbide, and the like. The substrate 20 may be a laminated substrate such as a silicon on insulator (SOI) substrate in which a SiO₂ film is laminated on a surface of a silicon substrate.

A major component of the lower electrode 30 is not particularly limited, and examples thereof include metals and metal oxides such as Au, Pt, Ir, IrO₂, RuO₂, LaNiO₃ and SrRuO₃; and combinations thereof.

A major component of the upper electrode 50 is not particularly limited, and examples thereof include the exemplary materials of the lower electrode 30; electrode materials which are used in a general semiconductor process such as Al, Ta, Cr, and Cu; and combinations thereof.

The thicknesses of the lower electrode 30 and the upper electrode 50 are not particularly limited and are, for example, about 200 nm.

In an ink jet recording head (liquid ejecting apparatus) 3, schematically, ink nozzles (liquid storage ejecting members) 70 are attached to a lower surface of the substrate 20 of the piezoelectric element 2 having the above-described configuration through a vibration plate 60 and include ink chambers (liquid storage chambers) 71 in which ink is stored and ink ejection openings (liquid ejection openings) 72 through which ink is ejected from the ink chambers 71 to the outside. The plural ink chambers 71 are provided according to the number of the convex portions 41 and the pattern of the piezoelectric film 40.

In the ink jet recording head 3, the electric field intensity applied to each of the convex portions 41 of the piezoelectric element 2 is increased and decreased such that the convex portion 41 expands and contracts. As a result, the ejection of ink from the ink chambers 71 and the ejection amount thereof are controlled.

Instead of attaching the vibration plate 60 and the ink nozzles 70 to the substrate 20 as separate members, a part of the substrate 20 may be processed into the vibration plate 60 and the ink nozzles 70. For example, when the substrate 20 is a laminated substrate such as a SOI substrate, the ink chamber 71 can be formed by etching the substrate 20 from the back surface side, and the vibration plate 60 and the ink nozzles 70 can be formed by processing the substrate.

The piezoelectric element 2 and the ink jet recording head 3 according to the embodiment are configured as described above.

[Ink Jet Recording Apparatus]

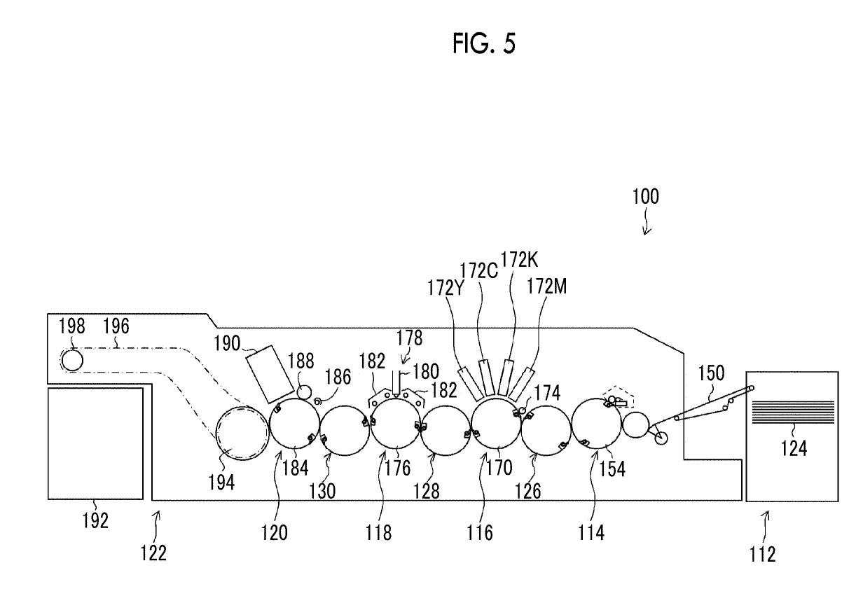

A configuration example of an ink jet recording apparatus including the ink jet recording heads 3 (172M, 172K, 172C, 172Y) will be described with reference to FIG. 5. FIG. 5 is a diagram showing an overall configuration of the apparatus.

The ink jet recording apparatus 100 is an impression cylinder direct drawing type ink jet recording apparatus in which a desired color image is formed on a recording medium 124 (also referred to as “sheet” for convenience) which is held at an impression cylinder (image drawing drum 170) of an image drawing unit 116 by ejecting plural color ink droplets to the recording medium 124 from the ink jet recording heads 172M, 172K, 172C, and 172Y. The ink jet recording apparatus 100 is also an on-demand type image forming apparatus to which a two-liquid reaction (aggregation) method of applying the process liquid (here, aggregation process liquid) to the recording medium 124 before the ejection of the ink such that the process liquid and the ink liquid react with each other so as to form an image on the recording medium 124 is applied.

As shown in the drawing, the ink jet recording apparatus 100 mainly includes a sheet feed unit 112, a process liquid applying unit 114, an image drawing unit 116, a drying unit 118, a fixing unit 120, and a discharge unit 122.

(Sheet Feed Unit)

The sheet feed unit 112 is a mechanism of supplying the recording medium 124 to the process liquid applying unit 114. In the sheet feed unit 112, the recording mediums 124 which are sheets of paper are laminated. The sheet feed unit 112 is provided with a sheet feed tray 150. The recording mediums 124 are fed from the sheet feed tray 150 to the process liquid applying unit 114 one by one.

(Process Liquid Applying Unit)

The process liquid applying unit 114 is a mechanism of applying the process liquid to a recording surface of the recording medium 124. The process liquid contains a colorant coagulant for causing a colorant (in this embodiment, a pigment) in ink, which is supplied from the image drawing unit 116, to aggregate. By bringing the process liquid and the ink into contact with each other, the separation between the colorant and a solvent is promoted in the ink.

The recording medium 124 to which the process liquid is applied by the process liquid applying unit 114 is delivered from a process liquid drum 154 to the image drawing drum 170 of the image drawing unit 116 through an intermediate transportation unit 126.

(Image Drawing Unit)

The image drawing unit 116 includes the image drawing drum (second transportation unit) 170, a sheet pressing roller 174, and the ink jet recording heads 172M, 172K, 172C, and 172Y.

It is preferable that each of the ink jet recording heads 172M, 172K, 172C, and 172 Y is a full-line type ink jet recording head (ink jet head) having a length corresponding to the maximum width of an image forming region in the recording medium 124. On an ink ejecting surface, a nozzle array in which plural nozzles for ejecting ink are arranged over the entire width of the image forming region is formed. Each of the ink jet recording heads 172M, 172K, 172C, and 172Y is provided to extend in a direction perpendicular to a transportation direction of the recording medium 124 (rotating direction of the image drawing drum 170).

The corresponding color ink droplets are ejected from the respective ink jet recording heads 172M, 172K, 172C, and 172Y to the recording surface of the recording medium 124 which is closely held on the image drawing drum 170. As a result, the ink comes into contact with the process liquid which has been applied from the process liquid applying unit 114 to the recording surface in advance, the colorant (pigment) dispersed in the ink aggregates, and a colorant aggregate is formed. Accordingly, the colorant is prevented from flowing on the recording medium 124, and an image is formed on the recording surface of the recording medium 124.

The recording medium 124 on which the image is formed by the image drawing unit 116 is delivered from the image drawing drum 170 to a drying drum 176 of the drying unit 118 through an intermediate transportation unit 128.

(Drying Unit)

The drying unit 118 is a mechanism of drying water contained in the solvent which is separated due to the colorant aggregation. As shown in FIG. 4, the drying unit 118 includes the drying drum (transportation unit) 176 and a solvent drying device 178.

The solvent drying device 178 is arranged at a position facing the outer peripheral surface of the drying drum 176 and includes IR heaters 182 and a warm air blowing nozzle 180 that is arranged between the IR heaters 182.

The recording medium 124 which is dried by the drying unit 118 is delivered from the drying drum 176 to a fixing drum 184 of the fixing unit 120 through an intermediate transportation unit 130.

(Fixing Unit)

The fixing unit 120 includes the fixing drum 184, a halogen heater 186, a fixing roller 188, and an in-line sensor 190. Due to the rotation of the fixing drum 184, the recording medium 124 is transported such that the recording surface faces outward. This recording surface is pre-heated by the halogen heater 186, is fixed by the fixing roller 188, and is inspected by the in-line sensor 190.

The fixing roller 188 is a roller member which applies heat and pressure to the dried ink such that self-dispersed thermoplastic resin fine particles in the ink coalesce to form a coating film from the ink. The fixing roller 188 is configured to apply heat and pressure to the recording medium 124.

According to the fixing unit 120 having the above-described configuration, the fixing roller 188 applies heat and pressure to the thermoplastic resin fine particles in the thin image layer formed by the drying unit 118. As a result, the thermoplastic resin fine particles coalesce and are fixed on the recording medium 124.

In addition, when the ink contains an UV-curable monomer, after water is sufficiently dried by the drying unit, the image is irradiated with UV rays using a fixing unit including an UV irradiation lamp such that the UV-curable monomer is cured and polymerized. As a result, the image intensity can be improved.

(Discharge Unit)

The discharge unit 122 is provided next to the fixing unit 120. The discharge unit 122 includes a discharge tray 192. A transfer roller 194, a transportation belt 196, and a tension roller 198 are provided between the discharge tray 192 and the fixing drum 184 of the fixing unit 120 so as to come into contact therewith. The recording medium 124 is transported to the transportation belt 196 by the transfer roller 194 and is discharged to the discharge tray 192.

In FIG. 5, the drum transport type ink jet recording apparatus is shown. However, the present invention is not limited to the drum transport type ink jet recording apparatus and can be applied to, for example, a belt transport type ink jet recording apparatus.

### EXAMPLES

Next, the present invention will be described in more detail using Examples, but the present invention is not limited thereto.

### Test Example 1

Piezoelectric films were formed while changing the doping amount of Nb and the carbon concentration in a raw material target, and piezoelectric characteristics thereof were evaluated.

### Example 1

A Ti film having a thickness of 20 nm and an (111) Ir film having a thickness of 150 nm as a lower electrode were sequentially formed on a Si wafer using a sputtering method. A Nb-PZT piezoelectric film was formed on the lower electrode. The total thickness of the Nb-PZT piezoelectric film was 2 μm.

Film formation conditions of the piezoelectric film were as follows.

Film formation device: RF sputtering apparatus (“ferroelectric film formation sputtering apparatus MPS series”, manufactured by Ulvac Inc.)

Target: Pb_{1.3}((Zr_{0.52}Ti_{0.48})₁₋ₓNbₓ)O₃ sintered compact having a diameter of 120 mmφ (x varied depending on the doping amount of Nb: when the doping amount of Nb was 14%, x=0.12 target, when the doping amount of Nb was 18%, x=0.15 target, and when the doping amount of Nb was 23%, x=0.20 target)

Film formation power: 500 W

Distance between substrate and target: 60 mm

Film formation pressure: 0.3 Pa

Film formation gas: Ar/O₂=97.5/2.5 (molar ratio)

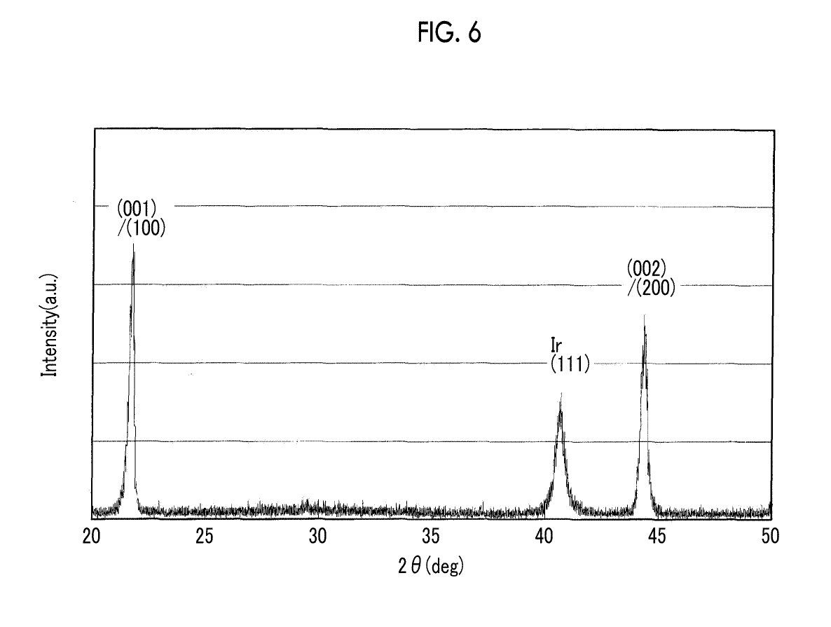

The obtained piezoelectric film was analyzed by X-ray diffraction (XRD) with a θ/2θ measurement method using “X-ray diffractometer ULTIMA for evaluation of a thin film” (manufactured by Rigaku Corporation). FIG. 6 shows an XRD pattern.

A peak of a pyrochlore phase was not observed, and the obtained piezoelectric film was a film having a single-phase perovskite structure and superior crystallinity. “Peak of a pyrochlore phase” appears in a region near 20=29.4°, which is a (222) plane of Pb₂Nb₂O₇ pyrochlore, and 2θ=34.1°±1° which is a (400) plane thereof.

The amount of pyrochlore (%) was calculated from ΣI(Pyrochlore)/(ΣI(Perovskite)+ΣI(Pyrochlore)). In the expression, ΣI(Pyrochlore) represents the total reflection intensity of the pyrochlore phase, and ΣI(Perovskite) represents the total reflection intensity of the perovskite phase. In this example, since a diffraction peak of the pyrochlore phase was not observed, the amount of pyrochlore was 0%.

Finally, a Ti/Pt upper electrode (Ti: 20 nm thick/Pt: 150 nm thick) was formed on the PZT film (Ti functioned as an adhesion layer, and Pt mainly functioned as an electrode). As a result, a piezoelectric element according to the present invention was obtained.

Regarding the obtained piezoelectric element, the relative dielectric constant ∈ and the dielectric loss tan δ were measured using an impedance analyzer Agilent 4294A. The piezoelectric potential was measured by processing the substrate into a diagram structure and applying a voltage of −10±10 V thereto using a laser Doppler vibrometer. The piezoelectric constant d₃₁ was calculated by causing the piezoelectric potential to match a simulation using calculation with ANSYS.

### Examples 2 and 3, Comparative Examples 1 to 5, Reference Example

Piezoelectric films were formed using the same method as in Example 1, except that the doping amount of Nb was changed to 14% (Comparative Examples 1 and 2), 20% (Example 2, Comparative Example 4), or 23% (Example 3, Comparative Example 5); and the carbon concentration in the raw material target during film formation was changed to 200 ppm (Comparative Example 1, Examples 2 and 3) or 600 ppm of a raw material of the related art (Comparative Examples 2, 3, 4, and 5). In addition, as a reference example, data of C92H (manufactured by Fuji Ceramics Corporation) which is known as a high-performance piezoelectric bulk body of the related art is also shown.

[Results]

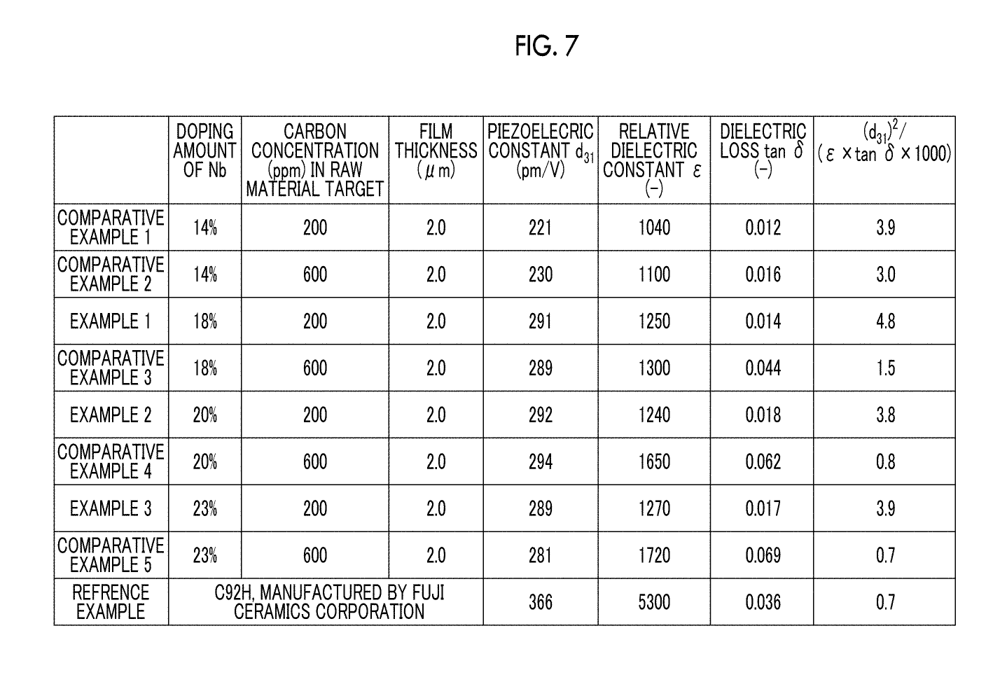

The results are shown in FIG. 7. As shown in Comparative Examples 1 and 2, when the doping amount of Nb was 14%, a high-quality piezoelectric film was able to be obtained irrespective of the carbon concentration in the raw material target. Among the favorable films in which the doping amount of Nb exceeded 14% and the piezoelectric constant was superior, in Comparative Examples 3 to 5 in which the raw material target having a carbon concentration of the related art was used, carbon supplied from the raw material or the like was likely to be incorporated, and the relative dielectric constant ∈ and the dielectric loss tan δ were high. It is considered that the power consumption of the piezoelectric films of Comparative Example 3 to 5 was high. In the piezoelectric films of Examples 1 to 3 which were formed using the materials in which the carbon concentration in the raw material target was low at 200 ppm, the piezoelectric constant was equivalent to the value of a piezoelectric film which was formed using a raw material target of the related art (carbon concentration: 600 ppm), the relative dielectric constant ∈ and the dielectric loss tan δ were able to be reduced, and the supply current and the power consumption were able to be reduced. Therefore, favorable films were able to be obtained.

In addition, as compared to the bulk ceramic of the related art as the reference example, a material having a higher piezoelectric constant than a thin film formed using a sputtering method was able to be obtained from the bulk ceramic. On the other hand, the relative dielectric constant ∈ and the dielectric loss tan δ were also increased, and the value of the following Equation (B) was also low at 0.7. Therefore, a high-quality material was not obtained. The mechanism for the increase in the relative dielectric constant ∈ and the dielectric loss tan δ of the bulk ceramic is not the same due to different material compositions; however, in the Examples of the present invention, piezoelectric films were formed in which the relative dielectric constant ∈ and the dielectric loss tan δ were low, and the supply current and the power consumption were reduced.

(d₃₁)²/(∈×tan δ×1000) (B)

### Test Example 2

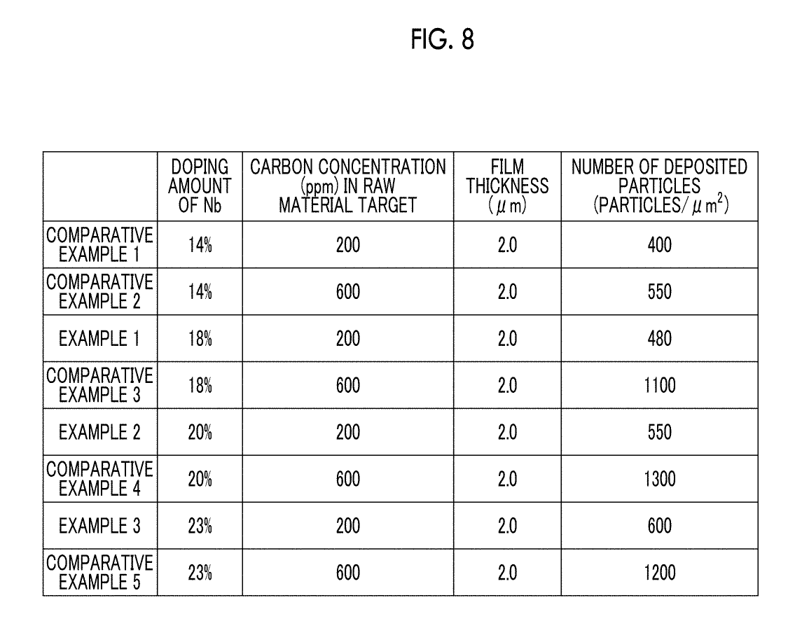

Next, regarding each of the piezoelectric films of Examples 1 to 3 and Comparative Examples 1 to 5 which were formed in Test Example 1, the number of particles having a particle size of 200 nm or more which were deposited on the surface of the piezoelectric film was investigated. The number of deposited particles was verified by counting the number of deposited particles per unit area in an electron microscope image. The results are shown in FIG. 8. It can be seen that, in the present invention, when the number of deposited particles is 1000 particle/μm² or less, the relative dielectric constant ∈ and the dielectric loss tan δ can be suppressed.

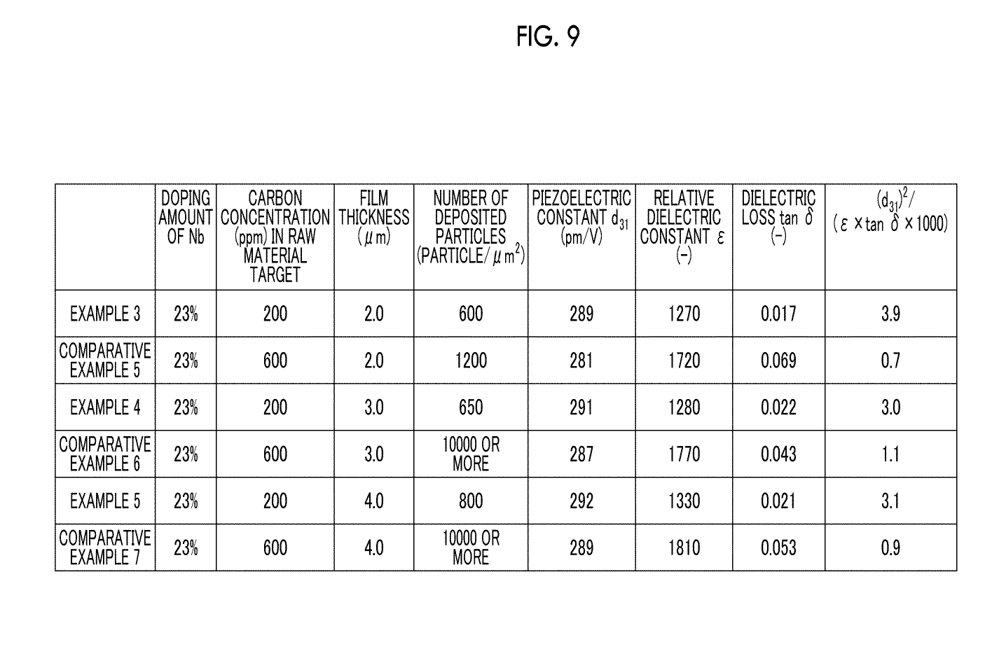

In addition, the doping amount of Nb was fixed to 23%, the thickness of the piezoelectric film was changed to 3 μm (Example 4, Comparative Example 6) or 4 μm (Example 5, Comparative Example 7), and the carbon concentration in the raw material target was changed. At this time, the number of deposited particles was investigated. The results are shown in FIG. 9. In Comparative Examples 5 to 7 in which the carbon concentration in the raw material target was high, the number of deposited particles was 1000 or more. In particular, in Comparative Example 6 having a thickness of 3 μm and Comparative Example 7 having a thickness of 4 μm, the films were covered with the deposited particles. “10000 or more” in FIG. 9 represents a state where the piezoelectric film was covered with the deposited particles. When Comparative Examples 6 and 7 were compared to each other, the deposition of particles was more significant in Comparative Example 7.

On the other hand, in Examples 3 to 5 in which the carbon concentration in the raw material target was reduced, the number of deposited particles was able to be reduced to be 1000 particle/μm² or less. In particular, in Examples 4 and 5 in which the thicknesses of the piezoelectric film were 3 μm and 4 μm, respectively, the number of deposited particles was able to be significantly reduced, which was efficient.

When the doping amount of Nb is 23%, the deposition of particles on the surface of the piezoelectric film is significant, but an effect on electric characteristics is not high. The reason for this is presumed to be as follows: the deposition relating to carbon occurs selectively on the surface of the piezoelectric film, and the amount of leakage in the piezoelectric film is small.

### EXPLANATION OF REFERENCES

1: sputtering apparatus
2: piezoelectric element
3, 172: ink jet recording head (liquid ejecting apparatus)
10: vacuum chamber
11: substrate holder
12: plasma electrode (cathode electrode)
13: RF power supply
14: gas introduction pipe
15: gas discharge pipe
20: substrate
30: lower electrode
40: piezoelectric film
41: convex portion
50: upper electrode
60: vibration plate
70: ink nozzle (liquid storage ejecting member)
71: ink chamber
72: ink ejection opening (liquid ejection opening)
100: ink jet recording apparatus
112: sheet feed unit
114: process liquid applying unit
116: image drawing unit
118: drying unit
120: fixing unit
122: discharge unit
124: recording medium
B: film formation substrate
G: gas
T: target
V: gas discharging

What is claimed is:

1. A piezoelectric film having a perovskite type crystal structure represented by the following Formula (P):
Pbₓ[(ZrₐTi₁₋ₐ)_{1-y}Nb_{y}]O_{z} (P)
where x represents a lead content, y represents a Nb content·B site doping amount, z represents an oxygen content, a represents a Zr/Ti ratio, and y>0.14, and although x=1.0 and z=3 is standard, numerical values of x and z may deviate from 1.0 and 3, respectively, within a range where a perovskite structure can be adopted,
wherein the piezoelectric film has a thickness of 2 μm or more, and
the number of particles containing carbon and having a particle size of 200 nm or more, which are deposited on a surface of the piezoelectric film, is 1000 particle/μm² or less.

2. The piezoelectric film as defined in claim 1, wherein the piezoelectric film has a thickness of 3 μm or more.

3. A method for manufacturing a piezoelectric film,
the piezoelectric film having a perovskite type crystal structure represented by the following Formula (P):
Pbₓ[(ZrₐTi₁₋ₐ)_{1-y}Nb_{y}]O_{z} (P)
where x represents a lead content, y represents a Nb content·B site doping amount, z represents an oxygen content, a represents a Zr/Ti ratio, and y>0.14, and although x=1.0 and z=3 is standard, numerical values of x and z may deviate from 1.0 and 3, respectively, within a range where a perovskite structure can be adopted,
the method comprising
forming a piezoelectric film with a sputtering method using a raw material target which has a composition corresponding to a film composition for forming the piezoelectric film and has a carbon concentration of 200 ppm or lower.

4. The piezoelectric film as defined in claim 1, wherein a piezoelectric constant d₃₁ (pm/V), a relative dielectric constant ∈ (−), and a dielectric loss tan δ (−) satisfy (d₃₁)²/(∈×tan δ×1000)>3.

5. The piezoelectric film as defined in claim 1, wherein crystals constituting the perovskite type crystal structure contain crystals, which are oriented in a (100) direction or a (001) direction, as a major component.

6. The piezoelectric film as defined in claim 1, wherein the piezoelectric film has a thickness of 2 μm to 10 μm.

7. The piezoelectric film as defined in claim 1, wherein y in Formula (P) satisfies y≥0.18.

8. The piezoelectric film as defined in claim 1, wherein the crystals constituting the perovskite type crystal structure are columnar crystals.
